(19) United States
(12) Patent Application Publication
(10) Pub. No.: US 2011/0120752 A1
(43) Pub. Date: May 26, 2011

(54) METHOD FOR FABRICATING A SOLAR BATTERY MODULE AND A WIRING SUBSTRATE FOR A SOLAR BATTERY

(75) Inventors: Noboru IMAI, Takahagi (JP); Ken Takahashi, Mito (JP); Katsutoshi Taga, Hitachi (JP); Aki Suzuki, Hitachi (JP)

(73) Assignee: HITACHI CABLE, LTD.

(21) Appl. No.: 12/949,207

(22) Filed: Nov. 18, 2010

(30) Foreign Application Priority Data
Nov. 20, 2009 (JP) 2009-264558

(51) Int. Cl. H05K 1/00; H01L 31/18

(52) U.S. Cl. 174/250; 438/64; 257/E31.093

(57) ABSTRACT

A method for fabricating a solar battery module includes cell preparing step for preparing a solar battery cell having an electrode wiring, wiring substrate preparing step for preparing a base material and a wiring substrate having a wiring pattern provided above the base material, mounting step for electrically connecting the wiring pattern with the electrode wiring and mounting the solar battery cell on the wiring substrate, and exposing step for removing the base material to expose the wiring pattern.

The present application is based on Japanese Patent Application No. 2009-264558 filed on Nov. 20, 2009, the entire contents of which are incorporated herein by reference.

### BACKGROUND OF THE INVENTION

1. Field of the Invention

The present invention relates to a method for fabricating a solar battery module and a wiring substrate for a solar battery, more particularly, to a method for fabricating a solar battery module and a wiring substrate for a solar battery in which a back contact type solar battery cell can be used.

2. Description of the Related Art

Conventionally, a solar battery module having a following configuration has been known. Namely, the conventional solar battery module includes a solar battery structure having a plurality of solar battery strings electrically connected to each other. In the solar battery structure, a substrate part of at least one of both ends facing to each other is installed to be bent in a direction opposite to a light-receiving plane of the solar battery cell. The solar battery string comprises a bus bar which is a part of a wiring in the bent substrate part. The plurality of solar battery strings are electrically connected to each other by electrically connecting the bus bars to each other. Japanese Patent Laid-Open No. 2009-43842 (JP-A 2009-43842) discloses one example of conventional solar battery modules.

According to the conventional solar battery module as disclosed in JP-A 2009-43842, it is possible to satisfy the requirement of reduction in thickness of the solar battery cell and to improve the power generating efficiency and characteristics of the solar battery module.

### SUMMARY OF THE INVENTION

However, in the solar battery module as disclosed in JP-A 2009-43842, a base material and an adhesive material that are components of the wiring substrate are sealed. Therefore, it is necessary to newly carry out a test for evaluating a long period reliability of the solar battery module which is called for a life cycle of ten years or more. It is further necessary to re-design the solar battery module based on the actual performance in the market. In the case where the base material and the adhesive material of the wiring substrate are sealed, a distortion may occur in the solar battery cell due to a difference in linear expansion coefficient between the base material and the solar battery cell and/or a difference in linear expansion coefficient between the adhesive material and the solar battery cell. When the distortion is large, deficiencies such as damage of the solar battery cell, disconnection of the wiring of a flexible printed circuit may occur.

Accordingly, an object of the present invention is to provide a method for fabricating a solar battery module and a wiring substrate for a solar battery, which has a simple structure, shows a long period reliability equal to or more than that of the conventional solar battery module, and satisfies a requirement of reduction in thickness.

According to a feature of the present invention, a method for fabricating a solar battery module comprises:

cell preparing step for preparing a solar battery cell having an electrode wiring;

wiring substrate preparing step for preparing a base material and a wiring substrate having a wiring pattern provided above the base material;

mounting step for electrically connecting the wiring pattern with the electrode wiring and mounting the solar battery cell on the wiring substrate; and

exposing step for removing the base material to expose the wiring pattern

The mounting step may comprise electrically connecting the electrode wiring to a part of the wiring pattern.

The mounting step may comprise forming a connecting portion and a non-connecting portion on the wiring pattern, in which the wiring pattern and the electrode wiring are electrically and physically connected to each other at the connecting portion, in which the wiring pattern and the electrode wiring do not physically contact with each other in the non-connecting portion.

The wiring substrate preparing step may comprise preparing the wiring substrate having an adhesive layer between the base material and the wiring pattern, and the exposing step may comprise peeling off the base material or the base material and adhesive layer from the wiring pattern.

The exposing step may comprise heating step for heating the wiring substrate or irradiation step for irradiating ultraviolet rays to the wiring substrate.

The wiring substrate preparing step may comprise preparing the wiring substrate in which a peel strength (in 90 degrees peeling at a pulling speed of 20 mm/minute) to the adhesive layer during or after the heating of the adhesive layer, or after irradiation of the ultraviolet rays to the adhesive layer is 100N/m or less.

The wiring substrate preparing step preferably comprises preparing the wiring substrate comprising a wiring having 0.2% proof stress of 100 MPa or less.

The wiring substrate preparing step preferably comprises preparing the wiring substrate comprising a wiring having a surface with a 10-point average surface roughness of 1.0 μm or less.

The wiring substrate preparing step may comprise preparing the wiring substrate having the wiring pattern comprising a rolled foil and including copper or a copper alloy.

The cell preparing step preferably comprises preparing the solar battery cell of a back contact type having a light-receiving plane on one side and the electrode wiring on other side.

The method may further comprise sealing step for sealing the exposed wiring pattern and the solar battery cell.

According to another feature of the invention, a wiring substrate for a solar battery comprises:

a base material;

an adhesive layer provided on a surface of the base material and having an adhesive force to be reduced by energy supply;

a first wiring for a first conductivity type provided in comb shape on a surface of the adhesive layer; and

a second wiring for a second conductivity type different from the first conductivity type, the second wiring being provided in comb shape on the surface of the adhesive layer at a region different from a region on which the first wiring is provided.

Tines of the first wiring and tines of the second wiring may be located alternately.

A peel strength (in 90 degrees peeling at a pulling speed of 20 mm/minute) of the first wiring and the second wiring to the adhesive layer to during or after the heating of the adhesive layer, or after irradiation of the ultraviolet rays to the adhesive layer is preferably 100N/m or less.

The first wiring and the second wiring preferably have 0.2% proof stress of 100 MPa or less.

The first wiring and the second wiring preferably have a surface with a 10-point average surface roughness of 1.0 μm or less.

### Effects of the Invention

According to the present invention, it is possible to provide a method for fabricating a solar battery module and a wiring substrate for a solar battery, which has a simple structure, shows a long period reliability equal to or more than that of the conventional solar battery module, and satisfies requirement of reduction in thickness.

### BRIEF DESCRIPTION OF THE DRAWINGS

The preferred embodiment according to the invention will be explained below referring to the drawings, wherein:

FIG. 1 is a plan view of a solar battery cell viewed from a back surface in a solar battery module in an embodiment according to the present invention;

FIG. 2A is a plan view of a flexible printed circuit to be used for manufacturing the solar battery module in the embodiment according to the present invention, and FIG. 2B is a cross-sectional view along A-A line of FIG. 2A;

FIG. 3 is a cross-sectional view of the solar battery module in the embodiment according to the present invention;

FIG. 4 is an explanatory diagram for showing a process of manufacturing the solar battery module in the embodiment according to the present invention;

FIGS. 5A and 5B are explanatory diagrams for showing the process of manufacturing the solar battery module in the embodiment according to the present invention;

FIGS. 6A and 6B are explanatory diagrams for showing the process of manufacturing the solar battery module in the embodiment according to the present invention; and

FIG. 7 is an explanatory diagram for showing the process of manufacturing the solar battery module in the embodiment according to the present invention.

### DETAILED DESCRIPTION OF THE PREFERRED EMBODIMENT

Next, an embodiment according to the present invention will be explained below in conjunction with appended drawings.

### Summary of the Embodiment

The embodiment of the present invention provides a method for fabricating a solar battery module cell preparing step for preparing a solar battery cell having an electrode wiring, wiring substrate preparing step for preparing a base material and a wiring substrate having a wiring pattern provided above the base material, mounting step for electrically connecting the wiring pattern with the electrode wiring and mounting the solar battery cell on the wiring substrate, and exposing step for removing the base material to expose the wiring pattern.

### The Embodiment

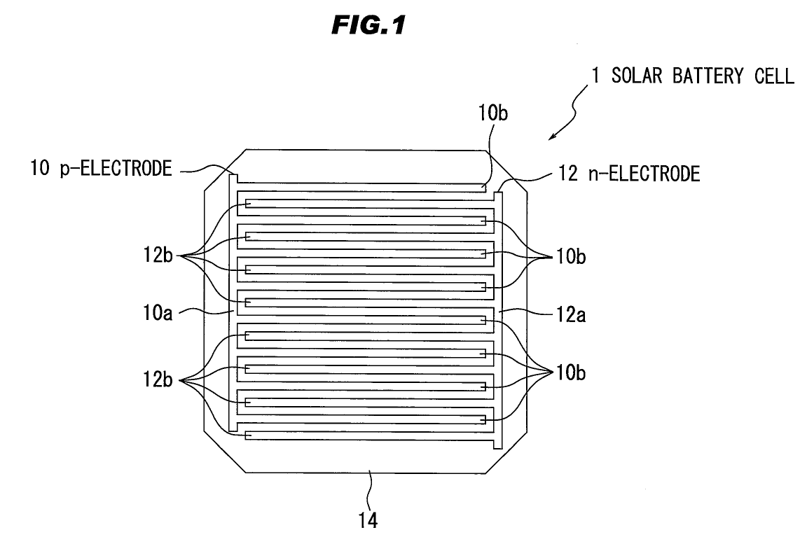

FIG. 1 is a plan view of a solar battery cell viewed from a back surface in a solar battery module in an embodiment according to the present invention.

### (Solar Battery Cell 1)

A solar battery cell 1 of a solar battery module 3 in the embodiment according to the invention comprises a semiconductor substrate 14 which is mainly composed of e.g. single crystal silicon, and an electrode wiring. More concretely, the solar battery cell 1 comprises the semiconductor substrate 14 formed from a predetermined semiconductor material in the shape of a flat plate, and the semiconductor substrate 14 comprises a light-receiving plane (i.e. a front surface) on one side and the electrode wiring on the other side (i.e. a back surface). In other words, the solar battery cell 1 in the embodiment is the back contact type solar battery cell 1, and the electrode wiring is not provided on the light-receiving plane. In addition, the electrode wiring comprises a p-electrode 10 and an n-electrode 12, and each of the p-electrode 10 and the n-electrode 12 is formed in comb shape. Furthermore, the comb-shaped p-electrode 10 and the comb-shaped n-electrode 12 are disposed in such a manner that tines of the comb-shaped p-electrode 10 and tines of the comb-shaped n-electrode 12 alternately engage with each other on the other side of the solar battery cell 1, respectively.

In addition, a plurality of p-side narrow electrodes 10b that are the tines of the p-electrode 10 and a plurality of n-side narrow electrodes 12b that are the tines of the n-electrode 12 are formed continuously in straight shape, respectively, in this embodiment. The p-side narrow electrodes 10b are formed to extend from a p-side outer electrode 10a, which is parallel to one side of the solar battery cell 1 in the plan view and provided in the vicinity of the one side, toward an opposite side of the one side. Similarly, the n-side narrow electrodes 12b are formed to extend from an n-side outer electrode 12a, which is provided in the vicinity of the opposite side of the one side and is parallel to the opposite side, toward the one side.

The electrode wiring (i.e. the p-electrode 10 and the n-electrode 12) may be mainly made of a material having excellent electric conductivity and excellent electric connecting property to a solder. By way of example only, the electrode wiring may be mainly composed of silver (Ag). In addition, a conductive (electroconductive) adhesive layer of silver paste or the like may be printed on a surface of the electrode wiring. In addition, the p-side narrow electrodes 10b and the n-side narrow electrodes 12b may be formed discontinuously in the shape of a dotted line, respectively.

The solar battery cell 1 may be mainly made of polycrystalline silicon. Alternatively, the solar battery cell 1 may be mainly made of other semiconductor, e.g. a III-V group compound semiconductor. Furthermore, locations of the p-electrode 10 and the n-electrode 12 may be reversed from the locations in this embodiment.

### (Flexible Printed Circuit 2)

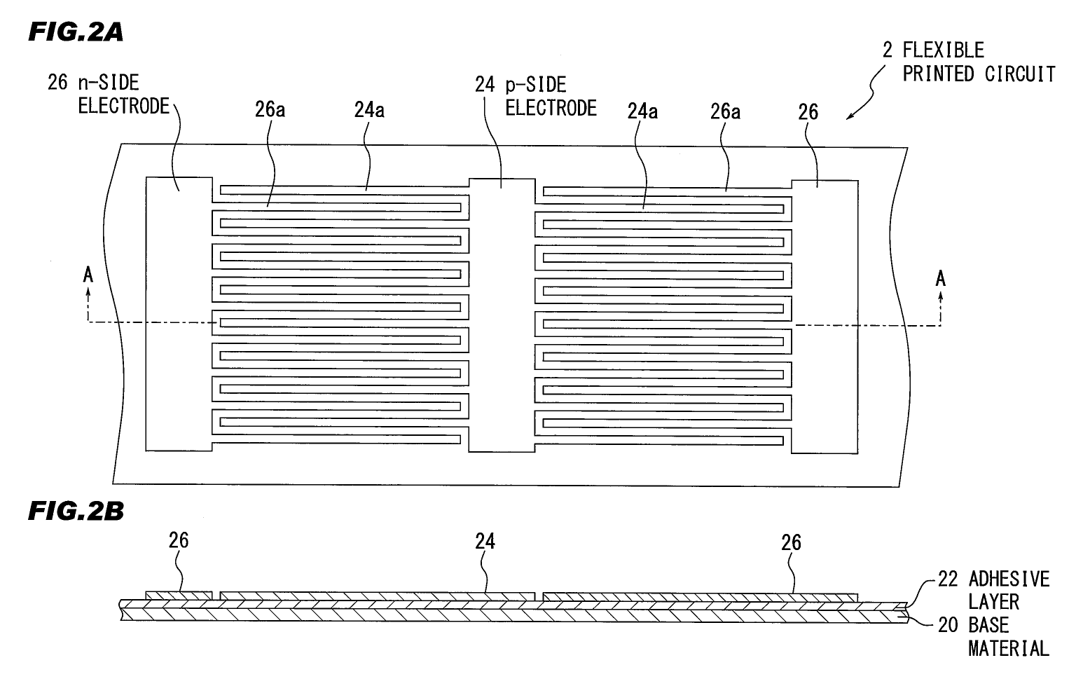

FIG. 2A is a plan view of a flexible printed circuit to be used for manufacturing the solar battery module in the embodiment according to the present invention, and FIG. 2B is a cross-sectional view along A-A line of FIG. 2A.

A flexible printed circuit 2 as a wiring substrate for a solar battery (i.e. the wiring substrate) to be used for fabricating the solar battery module 3 in this embodiment comprises a base material 20 having flexibility and a conductor wiring pattern (i.e. the p-side electrode 24 and the n-side electrode 26) as a wiring pattern to be provided above the base material 20, and further comprises an adhesive layer 22 provided between the base material 20 and the conductor wiring pattern. The adhesive layer 22 is provided generally on a substantially entire surface of the base material 20 or a part of the surface of the base material 20. The adhesive layer 22 may be provided by coating or laminating an epoxy-based adhesive. As the adhesive, for example, an adhesive material T (made by Arisawa Manufacturing Co., Ltd.) may be used.

### (Base Material 20)

The base material 20 is mainly made of an insulating material having flexibility and is formed in film shape. For example, the base material 20 is formed to have a thickness of 10 μm or more and 125 μm or less, in terms of easiness in handling, preferably a thickness of 25 μm or more and 75 μm or less. As the insulating material composing the base material 20, for example, polyethylene terephthalate (PET), polyethylenenaphthalate (PEN), polyimide, polyamide-imide and the like may be used.

### (Adhesive Layer 22)

The adhesive layer 22 is mainly made of an adhesive composition in which adhesive force is reduced by energy supply. As the adhesive composition, resin materials such as epoxy-based resin and acrylic resin may be used. In addition, as the energy supply, e.g. supply of heat energy by heating, supply of optical energy by irradiation of ultraviolet (UV) rays, or the like is proposed. In other words, the adhesive layer 22 comprises an adhesive composition, by which the adhesive force of the conductor wiring pattern to the adhesive layer 22 is reduced when a predetermined energy is supplied to the flexible printed circuit 2.

### (Conductor Wiring Pattern)

The conductor wiring pattern is mainly made of e.g. copper or copper alloy. In addition, the conductor wiring pattern preferably has a thickness of 18 μm or more and 75 μm or less in terms of reduction in stress which occurs due to reduction in direct current resistance, temperature variation or the like. Further, it is preferable that 0.2% proof stress of the conductor wiring pattern in total or in part is reduced to be about 100 MPa or less for the purpose of reducing the stress occurring in the solar battery cell 1 of the solar battery module 3 in this embodiment within a temperature-varying environment. Therefore, it is preferable that the conductor wiring pattern is formed from a rolled foil of metallic material.

Furthermore, in the conductor wiring pattern, it is preferable a surface roughness of at least a surface contacting to the adhesive layer 22 is a 10-point average surface roughness of 1.0 μm or less in the conductor wiring pattern in total or in part, for the purpose of enhancing easiness in peeling the adhesive layer 22 from conductor wiring pattern. In addition, a metal plating using gold, tin or the like may be provided on the surface of conductor wiring pattern for the purpose of preventing the conductor wiring pattern from discoloration, preventing corrosion from the conductor wiring pattern, and enhancing certainty in electrical connection of the conductor wiring pattern with the electrode wiring of the solar battery cell 1

More concretely, the conductor wiring pattern comprises a p-side electrode 24 which is formed in a comb shape on a surface of the adhesive layer 22 as a first wiring for p-type as a first conductivity type, and n-side electrodes 26 each of which is formed in a comb shape on the surface of the adhesive layer 22 as a second wiring for n-type as a second conductivity type opposite to the first conductivity type. The n-side electrodes 26 are provided at a region other than a region where the p-side electrode 24 is provided. More concretely, p-side narrow electrodes 24a that are tines of the p-side electrode 24 and n-side narrow electrodes 26a that are tines of the n-side electrodes 26 are disposed to be engaged with each other alternately.

Further, FIG. 2 shows a layout in which two solar battery cells 1 are mounted on the flexible printed circuit 2 as an example. In a variation of this embodiment, it is possible to use the flexible printed circuit 2 having a layout in which three or more solar battery cells 1 can be mounted. In addition, spacing between the solar battery cells 1, 1 and configuration of the conductor wiring pattern between the solar battery cells 1, 1 may be designed freely. In addition, it is preferable to determine the distance between the solar battery cells 1, 1 to be 1 mm or more for the purpose of preventing the solar battery cells 1, 1 from being damaged due to contact between the solar battery cells 1, 1. Furthermore, it is preferable to provide the flexible printed circuit 2 with a recognition pattern and/or recognition hole for positioning and mounting the solar battery cell 1.

As the flexible printed circuit 2, for example, an ultra thin rigid substrate having a base material 20 with a thickness of 60 μm or less, a copper foil-applied substrate having a surface-treated copper foil on which surface treatment such as plating process is previously (i.e. prior to the application of the copper foil to the base material) carried out, or a two-layer copper-applied substrate may be used. The two-layer copper-applied substrate includes a substrate formed by providing a metal layer on the base material 20 made of resin by using sputtering method or film formation method in vapor phase such as vacuum deposition, thereafter carrying out a copper plating on the metal layer, a substrate formed by casting resin on a copper foil, and a pseudo two-layer copper-applied substrate formed by adhering a base material 20 made of resin to a copper foil by using thermoplastic resin as an adhesive material. These two-layer copper-applied substrates may be used as the flexible printed circuit 2 to be used for fabricating the solar battery module 3 in this embodiment. In this case, the two-layer copper-applied substrate is manufactured with reducing a peel strength of a copper foil (to be adhered to the base material 20) with respect the base material 20.

In addition, the conductor wiring pattern may be formed by using a complex metal formed from a combination of copper and “invar” (registered trademark, Fe-36% Ni alloy). By using this complex metal, linear expansion coefficient of the conductor wiring pattern can be brought close to linear expansion coefficient of the solar battery cell 1.

### (Solar Battery Module 3)

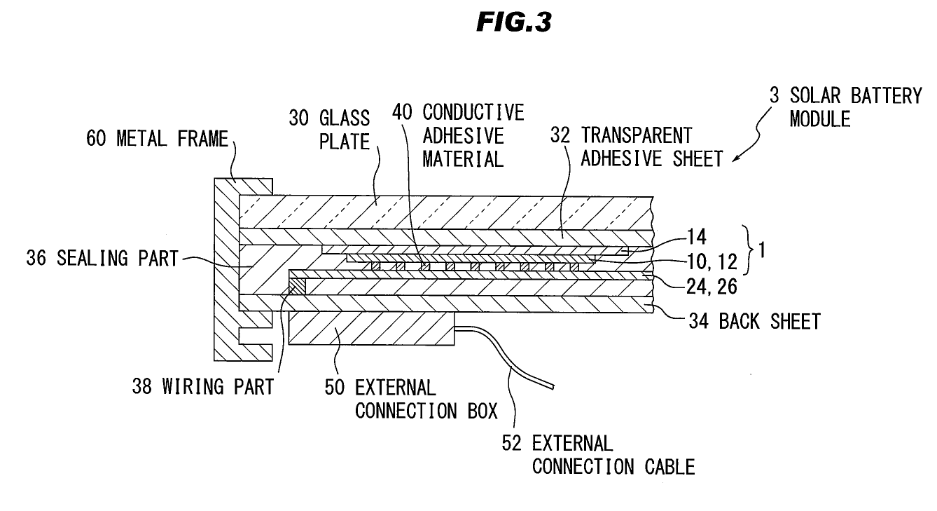

FIG. 3 is a cross-sectional view of the solar battery module in the embodiment according to the present invention.

The solar battery module 3 in this embodiment comprises the solar battery cell 1 and the conductor wiring pattern, which remains after removing the base material 20 and the adhesive layer 22 from the flexible printed circuit 2. More concretely, the solar battery module 3 in this embodiment comprises the solar battery cell 1, a conductive adhesive material 40 which electrically connects the p-electrode 10 and the n-electrode 12 of the solar battery cell 1 to the p-side electrode 24 and the n-side electrode 26 that are included in the flexible printed circuit 2, a sealing part 36 which seals the solar battery cell 1, the p-side electrode 24 and the n-side electrode 26, a transparent adhesive sheet 32 provided at the light-receiving plane of the solar battery cell 1, a glass plate 30 provided at the transparent adhesive sheet 32 on an opposite side to one side close to the solar battery cell 1, and a back sheet 34 provided at the p-side electrode 24 and the n-side electrode 26 on an opposite side to one side close to the solar battery cell 1.

The solar battery module 3 further comprises a wiring portion 38 which is electrically connected to the p-side electrode 24 and the n-side electrode 26, an external connection cable 52 which is electrically connected to the wiring portion 38, an external connection box 50 which accommodates a part of the external connection cable 52, and a metal frame 60 which sandwiches the glass plate 30 and the back sheet 34.

Next, the structure of the solar battery module 3 will be explained below together with the description of the manufacturing process of the solar battery module 3.

### (Manufacturing Process of the Solar Battery Module 3)

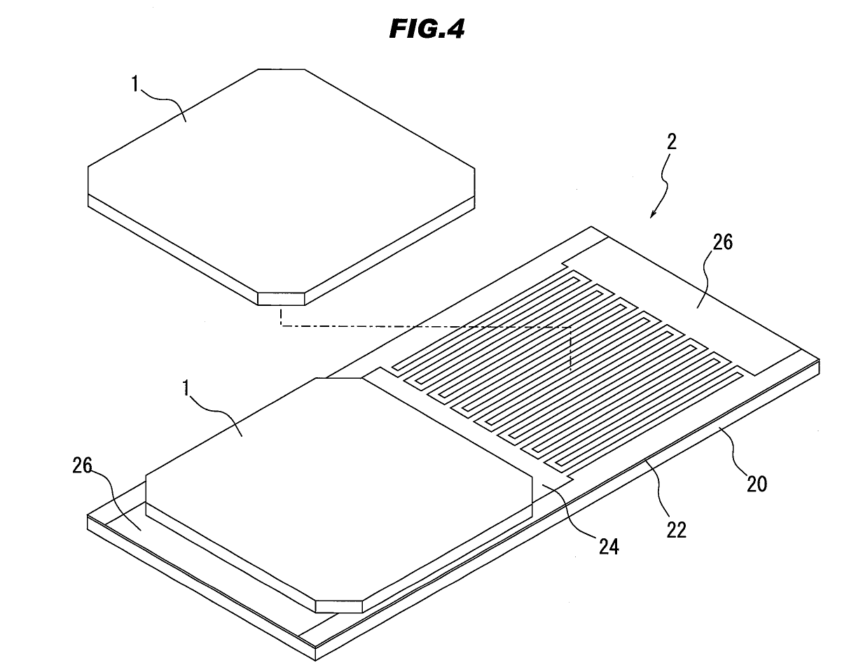

FIGS. 4, 5A-5B, 6A-6B and 7 are explanatory diagrams for showing the process of fabricating the solar battery module in the embodiment according to the present invention.

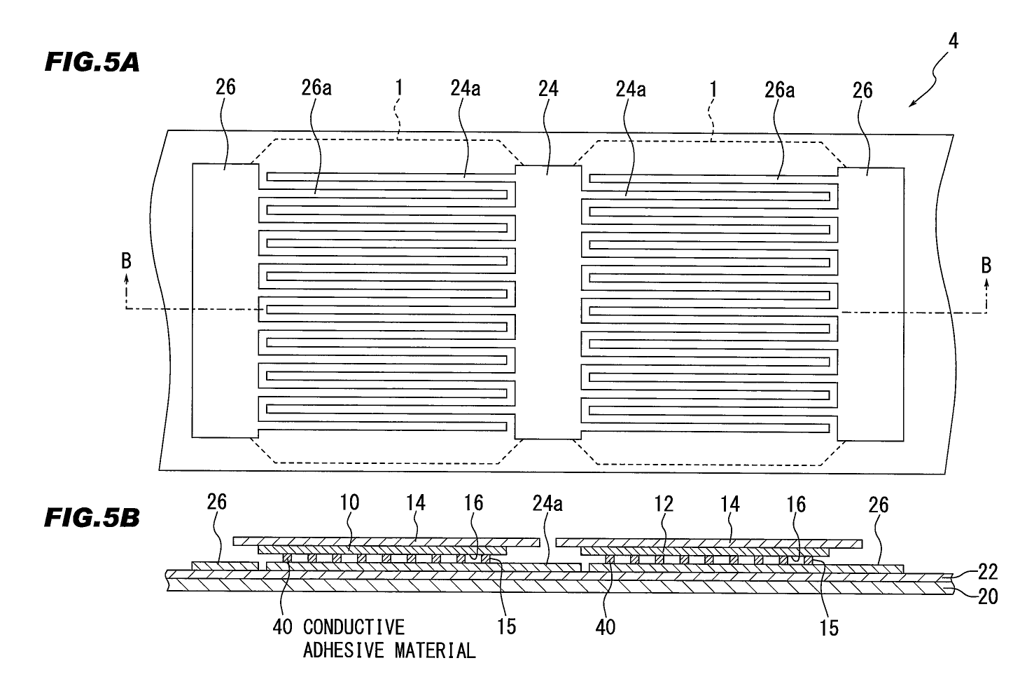

More concretely, FIG. 4 shows an outline of a process of mounting a solar battery cell on a flexible printed circuit. FIG. 5A shows a plan view in a state that the solar battery is mounted on the flexible printed circuit, and FIG. 5B shows a cross-section along B-B line of FIG. 5A. Herein, FIG. 5A is a plan view of a base material side on which the solar battery cell is not mounted.

### (Cell Preparing Step, Wiring Substrate Preparing Step, and Mounting Step)

At first, a solar battery cell 1 and a flexible printed circuit 2 are prepared (cell preparing step, wiring substrate preparing step). Thereafter, the solar battery cell 1 is mounted on the flexible printed circuit 2 (mounting step). More concretely, the solar battery cell 1 is mounted on the flexible printed circuit 2 such that a p-electrode 10 of the solar battery cell 1 is electrically connected to a p-side electrode 24 which is a wiring pattern of the flexible printed circuit 2, and the n-electrode 12 of the solar battery cell 1 is electrically connected to the n-side electrode 26 which is another wiring pattern of the flexible printed circuit 2.

In the mounting step in this embodiment, the p-electrode 10 and the n-electrode 12 are electrically connected to a part of the wiring pattern (i.e. the p-side electrode 24 and the n-side electrode 26). More concretely, in the mounting step, the solar battery cell 1 is mounted on the flexible printed circuit 2 such that a connecting portion 15 and a non-connecting portion 16 are formed on the wiring pattern. At the connecting portion 15, the p-electrode 10 and the n-electrode 12 are electrically or physically connected to the wiring pattern. On the other hand, at the non-connecting portion 15, the p-electrode 10 and the n-electrode 12 do not physically contact with the wiring pattern, namely, the p-electrode 10 and the n-electrode 12 are physically separated or distant from the wiring pattern.

For example, as shown in FIG. 5A, the connecting portion 15 is a portion which electrically connects the p-electrode 10 with the p-side electrode 24 partially (or intermittently) by means of a conductive adhesive material 40. The non-connecting portion 16 is formed between one connecting portion 15 and another connecting portion 15 which is adjacent to the one connecting portion 15. The non-connecting portion 16 is a portion for separating the p-electrode 10 from the p-side electrode 24. Therefore, the connecting portions 15 and the non-connecting portions 16 are provided alternately. Similarly, the connecting portions 15 and the non-connecting portions 16 are provided alternately between the n-electrode 12 and the n-side electrode 26. In addition, the non-connecting portion 16 is filled with e.g. a sealing resin composing a sealing part 36 as described later.

Herein, the conductive adhesive material 40 is formed previously (i.e. prior to the mounting process) by printing on surfaces of the p-electrodes 10 and the n-electrodes 12 of the solar battery cell 1 and surfaces of the p-side electrode 24 and the n-side electrodes 26 of the flexible printed circuit 2. Then, the solar battery cell 1 and the flexible printed circuit 2 are aligned mutually by using image recognition technique, so that the solar battery cell 1 is mounted on the flexible printed circuit 2. According to this process, a solar battery string 4 in which a plurality of solar battery cells 1 are serially-connected is formed as shown in FIGS. 5A and 5B.

Herein, the flexible printed circuit 2 may be formed into a strip sheet or a roll-shape when the solar battery cell 1 is mounted on the flexible printed circuit 2. In the case of using a roll-shaped flexible printed circuit 2, the solar battery string 4 may be cut into a sheet or string with a length corresponding to a total length of the solar battery cells 1 with the number to be mounted, prior to or after mounting the solar battery cell 1.

The reason for providing the connecting portions 15 and the non-connecting portions 16 in accordance with the shape of the wiring pattern is to prevent the damage to the solar battery cell 1 and the deterioration of the workability in the manufacturing process of the solar battery module 3, when warping occurs in the solar battery cell 1. Therefore, it is preferable that a pitch (distance) between the adjacent connecting portions 15 is adjusted in accordance with variation in thickness of the solar battery cell 1 and change in structure of the flexible printed circuit 2. In addition, the warping of the solar battery cell 1 can be reduced by heating only a part of the conductive adhesive material 40 or by heating only the solar battery cell side, when mounting the solar battery cell on the flexible printed circuit 2 via the conductive adhesive material 40.

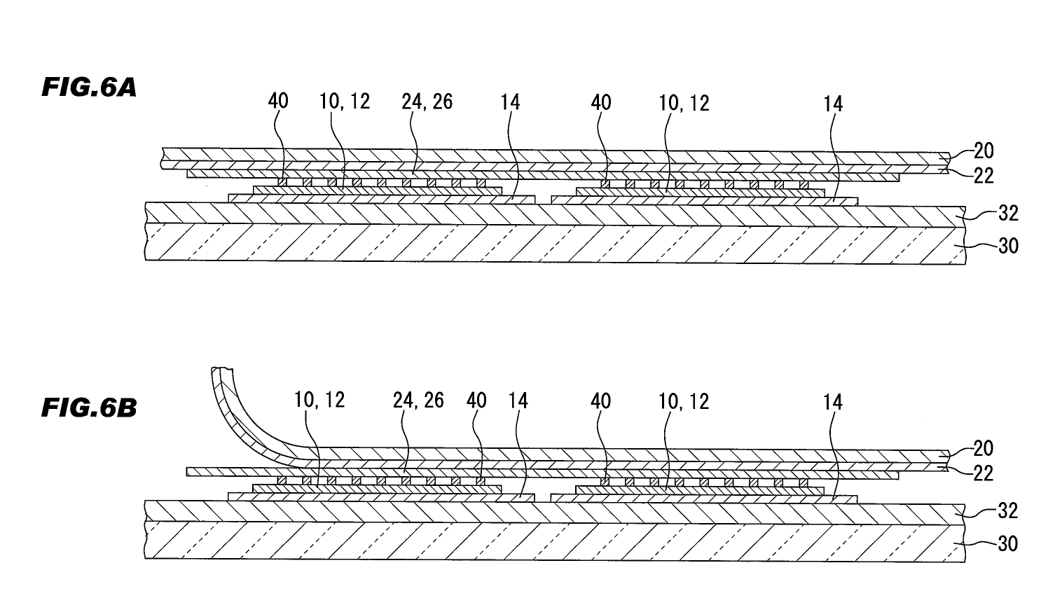

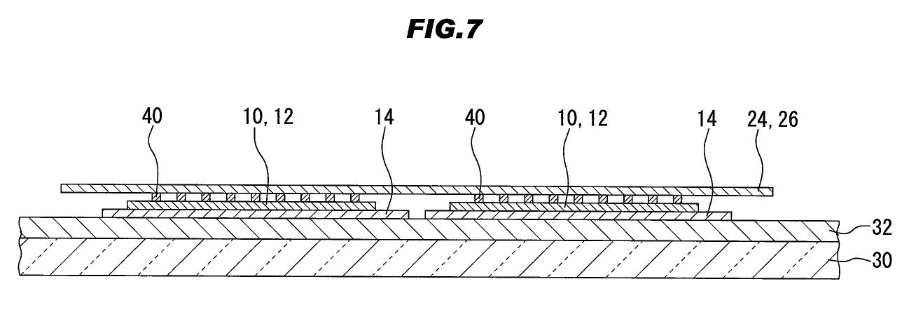

FIG. 6A shows a schematic diagram of a cross section in the state where the glass plate is adhered to the solar battery string via the transparent adhesive sheet, and FIG. 6B shows a schematic diagram of a cross section during the peeling off of the base material and the adhesive layer of the flexible printed circuit. FIG. 7 shows a schematic diagram of a cross section after removing the base material and the adhesive layer of the flexible printed circuit from the solar battery string.

### (Attaching Step)

At first, a glass plate 30 on which a transparent adhesive sheet 32 is stuck on one side is prepared. Then, a surface of semiconductor substrate 14 of the solar battery string 4 is adhered to a surface of the transparent adhesive sheet 32 on the other side opposite to the one side on which the glass plate 30 is stuck (Attaching step). More concretely, the transparent adhesive sheet 32 is mainly formed from polyethylene-vinyl acetate (EVA) based resin or silicone-based resin. In addition, the transparent adhesive sheet 32 may have a wavelength conversion function for converting a short wavelength light included in the sunlight into a light with a such wavelength that can generate electricity in the solar battery cell 1. The solar battery string 4 is disposed on the surface of the transparent adhesive sheet 32 on the other side opposite to the one side on which the glass plate 30 is stuck, so that the transparent adhesive sheet 32 and the solar battery cell 1 are disposed to cohere or adhere to each other. When the adhesive force between the transparent adhesive sheet 32 and the solar battery cell 1 is insufficient, the adhesive force may be improved by heating the transparent adhesive sheet 32.

### (Exposing Step)

Next, by removing the base material 20 from the surface of the p-side electrode 24 as the wiring pattern and the surfaces of the n-side electrodes 26 as the wiring pattern as shown in FIG. 6B, a back surface of the p-side electrode 24 and a back surface of each of the n-side electrodes 26 are exposed. Namely, surfaces on the opposite side of the p-side electrode 24 and the n-side electrodes 26 that are connected to the p-electrodes 10 and the n-electrodes 12 are exposed (exposing step). At the exposing step, the base material 20 or the base material 20 and adhesive layer 22 are peeled off from the surface of the p-side electrode 24 and the surfaces of the n-side electrodes 26, so that the back surface of the p-side electrode 24 and the back surfaces of the n-side electrodes 26 are exposed.

Concretely, the exposing step includes a heating step for heating the flexible printed circuit 2 and/or the adhesive layer 22 in accordance with characteristics of an adhesive composition composing the adhesive layer 22 of the flexible printed circuit 2, and an irradiation step for irradiating ultraviolet (UV) rays to the flexible printed circuit 2 and/or the adhesive layer 22. At the exposing step, the back surface of the p-side electrode 24 and the back surfaces of the n-side electrodes 26 are exposed, by peeling off the adhesive layer 22 and the base material 20 in that the adhesive force is reduced by the heating step or the irradiation step from the p-side electrode 24 and the n-side electrodes 26, as shown in FIG. 6B.

More concretely, the exposing step comprises the heating step or the irradiation step as a step for supplying the energy with a predetermined energy amount directly or indirectly to the adhesive layer 22 of the flexible printed circuit 2. For example, as the heating step, a step for heating the flexible printed circuit 2, a step for heating the adhesive layer 22 by irradiating the infrared rays to the adhesive layer 22 or the like may be used. At the exposing step, the base material 20 and the adhesive layer 22 are peeled off from the p-side electrode 24 and the n-side electrodes 26, after reducing the adhesive force of the adhesive layer 22 by the heating step or the irradiation step. According to this process, the solar battery string 4, from which the base material 20 and the adhesive layer 22 are removed, is formed as shown in FIG. 7.

In the peeling off of the base material 20 and the adhesive layer 22, it is possible to reduce the affect on the cohesion or adhesion between the transparent adhesive sheet 32 and the solar battery cell 1 by peeling the base material 20 and the adhesive layer 22 along an orientation with an angle of 150 degrees or more and 180 degrees or less with respect to the surface of the glass plate 30. In particular, at the time of starting the peeling off of the base material 20 and the adhesive layer 22, a portion in which the p-side electrode 24 and the n-side electrodes 26 are not connected to the p-electrodes 10 and the n-electrodes 12 may be fixed by a clamp or the like.

In the wiring substrate preparing step, it is preferable to prepare a flexible printed circuit 2 having the adhesive layer 22, for which a peel strength (in 90 degrees peeling at a pulling speed of 20 mm/minute) of the wiring pattern (i.e. the p-side electrode 24 and the n-side electrodes 26 for each or in total) to the adhesive layer 22 during or after the heating of the adhesive layer 22, or after irradiation of the ultraviolet (UV) rays to the adhesive layer is 100N/m or less.

### (Cleaning Step)

After the base material 20 and the adhesive layer 22 are peeled off from the p-side electrode 24 and the n-side electrodes 26, the back surface of the p-side electrode 24 and the back surface of the n-side electrodes 26 may be cleaned by using the normal pressure plasma (cleaning step). In addition, after the base material 20 and the adhesive layer 22 are peeled off from the p-side electrode 24 and the n-side electrodes 26, a conductive adhesive material, a solder paste or the like may be coated or printed on the back surface of the p-side electrode 24 and the back surfaces of the n-side electrodes 26, namely the back surface of the p-side electrode 24 and the back surfaces of the n-side electrodes 26 that are exposed to the outside by the peeling off of the base material 20 and the adhesive layer 22 (i.e. the surfaces on the side opposite to the side to which the conductive adhesive material 40 is connected). Then, it is possible to improve the connection strength between the p-side electrode 24 and n-side electrodes 26 and the p-electrodes 10 and n-electrodes 12, by heating a region on which the conductive adhesive material or the like is coated or printed to melt the conductive adhesive material or the like, thereby flowing the melt conductive adhesive material or the like from the back surface side of the p-side electrode 24 and the n-side electrodes 26 toward the front surface side (i.e. the surface to which the conductive adhesive material 40 of the p-side electrode 24 and n-side electrodes 26 are connected). According to this step, it is possible to compensate the connection strength when the connection strength between the p-side electrode 24 and n-side electrodes 26 and the p-electrodes 10 and n-electrodes 12 are insufficient.

### (Module Forming Step)

Successively, a wiring portion as a wiring member and an external connecting wiring member (not shown) are attached to the solar battery string 4. Then, the solar battery cell 1, the p-side electrode 24 and the n-side electrodes 26 are sealed by using the sealing resin such as polyethylene-vinyl acetate (EVA resin) or the like, to provide a sealing part 36 (sealing step). Furthermore, a back sheet 34 is provided over (accumulated on) a surface of the sealing part 36, then degassed and heated. Thereafter, a metal frame 60 comprising e.g. aluminum, an external connection box 50 and an external connection cable 52 are installed. According to this step, the solar battery module 3 in this embodiment as shown in FIG. 3 is provided.

### (Variations)

A peelable copper foil (copper foil with copper foil carrier manufactured by Mitsui Mining & Smelting Co., Ltd.), i.e. a copper foil which separates by itself into two layers may be applied to the flexible printed circuit 2. In this case, the copper foil per se is peeled off from the flexible printed circuit 2, so that it is applicable to manufacturing of the solar battery module 3 in this embodiment.

The adhesive composition composing the adhesive layer 22 may remain on the surfaces of the p-side electrode 24 and n-side electrodes 26 after peeling off the base material 20 and the adhesive layer 22 except a region on which the wiring portion is provided. Further, the base material 20 and the adhesive layer 22 may be partially peeled off. For example, only a part corresponding to end parts of the p-side electrode 24 and the n-side electrodes 26 or a part corresponding to a space between the solar battery cells 1 of the base material 20 and the adhesive layer 22 may be peeled off.

### Effects of the Embodiment

According to a method for fabricating the solar battery module 3 in this embodiment, the solar battery cell 1 is sealed after the solar battery cell 1 is mounted on the flexible printed circuit 2, then the base material 20 and the adhesive layer 22 composing the flexible printed circuit 2 are removed. Therefore, the p-side electrode 24 and the n-side electrodes 26 of the flexible printed circuit 2 and the solar battery cell 1 are mainly sealed by the sealing resin. Accordingly, it is possible to simplify the long-term reliability test and demonstration test for the solar battery module 3 manufactured by the method for fabricating the solar battery module 3 in this embodiment. Therefore, it is possible to reduce a required period and cost for search and development particularly of the back contact type solar battery module 3.

Further, in the solar battery module 3 in this embodiment, since the base material 20 and the adhesive layer 22 composing the flexible printed circuit 2 are removed and not sealed by the sealing part 36, it is possible to significantly suppress the deterioration of insulation resistance of the sealing part 36 due to resolution of the base material 20 and the adhesive layer 22 caused by the UV rays exposure during long-term use, the deterioration of the insulation resistance of the sealing part 36 due to hydrolysis of the base material 20 and the adhesive layer 22 caused by moisture absorption, or the deterioration of the insulation resistance of the sealing part 36 due to chemical reaction between the EVA resin and the base material 20 and adhesive layer 22.

Still further, according to the method for fabricating the solar battery module 3 in this embodiment, since the base material 20 and adhesive layer 22 are removed from the flexible printed circuit 2, it is possible to realize the solar battery module 3 having a simple configuration, and to reduce the thickness of the solar battery module 3. Since the p-side electrode 24, the n-side electrodes 26 and the solar battery cell 1 are mainly sealed in the sealing part 36 while the base material 20 and the adhesive layer 22 are not sealed in the sealing part 36, it is possible to prevent the generation of stress in the solar battery cell 1 due to the difference between the linear expansion coefficients of the base material 20 and adhesive layer 22 and the linear expansion coefficient of the solar battery cell 1. Furthermore, since the adhesive layer 22 of the flexible printed circuit 2 is mainly composed of the material in which the adhesive force is reduced by the energy supply, it is possible to reduce residues at the adhesive layer 22 on the surfaces of the p-side electrode 24 and n-side electrode 26 when the base material 20 and adhesive layer 22 are peeled off.

Although the invention has been described, the invention according to claims is not to be limited by the above-mentioned embodiments and examples. Further, please note that not all combinations of the features described in the embodiments and the examples are not necessary to solve the problem of the invention.

1. A method for fabricating a solar battery module comprising:
cell preparing step for preparing a solar battery cell having an electrode wiring;
wiring substrate preparing step for preparing a base material and a wiring substrate having a wiring pattern provided above the base material;
mounting step for electrically connecting the wiring pattern with the electrode wiring and mounting the solar battery cell on the wiring substrate; and
exposing step for removing the base material to expose the wiring pattern.

2. The method according to claim 1, wherein the mounting step comprises electrically connecting the electrode wiring to a part of the wiring pattern.

3. The method according to claim 2, wherein the mounting step comprises forming a connecting portion and a non-connecting portion on the wiring pattern,
wherein the wiring pattern and the electrode wiring are electrically or physically connected to each other at the connecting portion,
wherein the wiring pattern and the electrode wiring do not physically contact with each other in the non-connecting portion.

4. The method according to claim 3, wherein the wiring substrate preparing step comprises preparing the wiring substrate having an adhesive layer between the base material and the wiring pattern, and the exposing step comprises peeling off the base material or the base material and adhesive layer from the wiring pattern.

5. The method according to claim 4, wherein the exposing step comprises heating step for heating the wiring substrate or irradiation step for irradiating ultraviolet rays to the wiring substrate.

6. The method according to claim 5, wherein the wiring substrate preparing step comprises preparing the wiring substrate in which a peel strength in 90 degrees peeling at a pulling speed of 20 mm/minute to the adhesive layer during or after the heating of the adhesive layer, or after irradiation of the ultraviolet rays to the adhesive layer is 100N/m or less.

7. The method according to claim 1, wherein the wiring substrate preparing step comprises preparing the wiring substrate comprising a wiring having 0.2% proof stress of 100 MPa or less.

8. The method according to claim 7, wherein the wiring substrate preparing step comprises preparing the wiring substrate comprising a wiring having a surface with a 10-point average surface roughness of 1.0 μm or less.

9. The method according to claim 8, wherein the wiring substrate preparing step comprises preparing the wiring substrate having the wiring pattern comprising a rolled foil and including copper or a copper alloy.

10. The method according to claim 9, wherein the cell preparing step comprises preparing the solar battery cell of a back contact type having a light-receiving plane on one side and the electrode wiring on other side.

11. The method according to claim 10, further comprising:
sealing step for sealing the exposed wiring pattern and the solar battery cell.

12. A wiring substrate for a solar battery comprising:
a base material;
an adhesive layer provided on a surface of the base material and having an adhesive force to be reduced by energy supply;
a first wiring for a first conductivity type provided in comb shape on a surface of the adhesive layer; and
a second wiring for a second conductivity type different from the first conductivity type, the second wiring being provided in comb shape on the surface of the adhesive layer at a region different from a region on which the first wiring is provided.

13. The wiring substrate for a solar battery according to claim 12, wherein tines of the first wiring and tines of the second wiring are located alternately.

14. The wiring substrate for a solar battery according to claim 13, wherein a peel strength in 90 degrees peeling at a pulling speed of 20 mm/minute of the first wiring and the second wiring to the adhesive layer to during or after the heating of the adhesive layer, or after irradiation of the ultraviolet rays to the adhesive layer is 100N/m or less.

15. The wiring substrate for a solar battery according to claim 14, wherein the first wiring and the second wiring have 0.2% proof stress of 100 MPa or less.

16. The wiring substrate for a solar battery according to claim 15, wherein the first wiring and the second wiring have a surface with a 10-point average surface roughness of 1.0 μm or less.
